(19) United States
(12) Patent Application Publication
(10) Pub. No.: US 2009/0194146 A1
(43) Pub. Date: Aug. 6, 2009

(54) Method and apparatus for arranging multiple flat reflector facets around a solar cell or solar panel

(76) Inventor: Daniel Simon, Chicago, IL (US)

Correspondence Address: Daniel Simon, Apt. # 1003, 5555 N. Sheridan Road, Chicago, IL, 60640, US

(21) Appl. No.: 12/012,801

(22) Filed: Feb. 6, 2008

(51) Int. Cl. H01L 31/058; H01L 31/0232; F24J 2/46

(52) U.S. Cl. 136/248; 136/259; 126/704

(57) ABSTRACT

A system and method of arranging multiple flat reflective facets around solar cells within a solar panel, or around a standard solar panel to increase the amount of light striking the solar cells or panel. The present invention in the preferred embodiment uses multiple reflector facets arranged to form an inverted pyramid shell where the apex of the pyramid is removed and replaced by a solar cell or panel. Accordingly each flat reflective facet has an isosceles trapezoid shape and has its shorter parallel side located adjacent and at a 120 degree angle to the solar cell or panel. This geometry ensures uniform illumination of the solar cell provided the reflector is approximately the same width as the solar cell; such uniform illumination may be especially helpful for PV generating applications. An alternate embodiment employs only three flat reflective facets, rather than four, around a standard solar panel. Flat reflective facets cost less than solar cells or panels, so employing these arrangements should lower the average cost of solar power.

### BACKGROUND

1. Field of Invention

This invention relates generally to solar panels and more specifically to an improved arrangement of multiple reflector facets around solar cells within a solar panel, or alternately around the outside of solar panels.

2. Description of the Prior Art

There is a substantial interest in the commercial application of solar energy. Even as the cost of other energy sources rise, a main obstacle to widespread adoption of solar power is the high cost of solar devices, especially solar photovoltaic cells. This is generally due to the high cost of materials used to convert solar energy into thermal or electrical energy, especially relative to reflector materials. It is well known in the art to use a solar cell for intercepting sunlight and producing energy of a thermal or electrical nature or the combination of both. A solar device or solar cell generally can mean a receiver or thermal absorbing plate (for solar thermal applications) or a solar photovoltaic (PV) cell (for solar electrical applications). Moreover it is fairly common knowledge that if more sunlight reaches a solar cell, one can convert proportionally more solar energy into thermal or electrical energy. Solar cells are frequently connected or joined to other cells either in parallel or in series and once a useful number are assembled they are generally enclosed in what is commonly called a panel.

A panel frequently has a transparent cover, parallel to and above the plane of the solar cells which allows sunlight to enter the panel and strike the solar cells. The panel frequently has a frame with sides and a backing plate that define a weather tight enclosure that shield the solar cell from the elements.

The prior art contains many examples of arrangements of solar cells and reflectors within a panel. Much of the prior art use reflectors on one or at most two sides of each solar cell, as taught in U.S. Pat. Nos. 6,528,716 5,538,563 and 4,316,448. While these arrangements reduce the amount of costly solar cell materials somewhat, they still include the inefficient or wasteful use of expensive materials.

The prior art also contains examples of panels using hard to manufacture circular, conic or parabolic reflectors, to increase the amount of sunlight reaching a solar cell. Some examples include U.S. Pat. Nos. 4,199,376 and 2,904,612 which both utilize complex three dimensional shapes to reflect light onto round solar cells (as they used to be made) from the region in between the round solar cells within a rectangular solar panel. There are numerous prior art example of complex reflector geometries many of which are used to increase sunlight arriving at solar devices, especially for use with solar thermal energy conversion or hybrid electric-thermal systems including U.S. Pat. Nos. 5,419,782 and 4,248,643. Disadvantages of these types of arrangements include complex geometries which are difficult to make and costly to reproduce.

Finally the prior art contains numerous examples of arrangements of multiple reflective facets used for different solar applications, such as solar cooking. Examples of such prior art include U.S. Pat. No. 4,637,376 to Varney and U.S. Pat. No. 4,292,957 to Golder and U.S. Pat. Nos. 4,220,141 and 4,077,391 to Way Jr. The prior art of Varney contains a reflector arrangement with some elements in common with this invention, but his invention has numerous additional elements primarily related to solar cooking that are not required for the manufacture and/or use of solar panels.

It would be advantageous to have a method and apparatus that uses inexpensive flat reflective facets and a simple to implement geometry to increase or concentrate the amount of sunlight falling on a solar cell or panel. Given the much higher cost of solar cells or panels relative to the cost of reflective facets or reflectors, this invention can reduce the average cost of solar power and allow many more people to benefit from clean, abundant, and renewable solar energy.

### SUMMARY OF THE INVENTION

The present invention relates to a method and apparatus for arranging multiple reflector facets around a solar cell or panel. The present invention in a preferred embodiment uses multiple reflector facets arranged to form an inverted pyramid shell where the apex of the pyramid is removed and replaced by a solar cell or panel. Assuming the solar cell is square, there will be four equal sized isosceles trapezoid shaped flat reflector facets used, each one with the shorter parallel side located adjacent to the solar cell and with the reflective face tilted at a 120 degree angle from the surface of the solar cell. The angle between the solar cell and the reflective facet is important as it ensures uniform illumination of the solar cell provided the length of the solar cell is approximately equal to the length of the reflective facet.

If the solar panel (or cell) is rectangular, the reflective facet faces will have the shorter parallel side located adjacent to the solar panel, with the reflective face tilted at a 120 degree angle from the panel's surface, and the shorter parallel reflector sides ought to be the same length as the panel sides they are placed adjacent to.

While a panel that incorporates this inverted pyramid arrangement of reflector facets will be deeper than a standard panel, this design enables a much stronger panel to be constructed. The regular spaced reflector facets allow uniform support, either by the facets themselves or by adding a top to bottom vertical support midway between each solar cell at the point where the facets meet at the top of the panel. It is well known that regularly spaced vertical support will produce a much stronger structure than one which is primarily supported along the edges. The result is that one can construct a much stronger panel using the materials of standard panel construction, or one may construct an equivalently strong panel using less expensive materials.

### Objects and Advantages

1. A simple arrangement of flat reflector facets around a solar cell (or panel) that increases the amount of sunlight striking the solar cell (or panel). Because flat reflector facets are much cheaper than solar cells (or panels), this arrangement reduces the average cost of power.
2. This panel design enables one to use regularly spaced vertical supports, both lengthwise and widthwise throughout the panel, making for a stronger panel than is common if the panel is primarily supported along the edges.
3. This invention can be practiced by the solar panel manufacturer who may integrate the reflector facets into the panel around each solar cell within the solar panel, or by the end user of a traditionally designed solar panel who may add the reflector facets to the exterior of the solar panel as described.
4. The reflector facets can be designed to reflect the most useful segment of the solar spectrum for the solar cell application. If one is generating electricity and the photovoltaic solar cell has a preferred band of solar spectrum, one can design the reflector facets to preferentially reflect more of that spectrum than other bands which might tend to overheat or otherwise degrade the cell.

Any solar panel generates more power if it is placed on a solar tracking system and solar panels made with the reflector arrangement(s) described above (either inside or outside the panel) will likewise benefit from solar tracking.

Further objects and advantages of my invention will become apparent from a consideration of the drawings and ensuing description.

### DESCRIPTION OF THE DRAWINGS

FIG. 1 shows a perspective view of a solar panel with multiple reflector facets arranged around individual solar cells within the solar panel.

FIG. 2 shows a side view of multiple reflector facets arranged around an individual solar cell within the solar panel.

FIG. 3 shows a perspective view of multiple reflector facets arranged around the outside of a standard solar panel.

FIG. 4 shows a perspective view of reflector facets arranged around only 3 sides of a standard solar panel.

FIG. 5 shows a perspective view of the back of a solar panel with reflective facets attached.

FIG. 6 shows a detailed view of a method of mounting the reflective facets to the solar panel sides using screws.

FIG. 7 shows a detailed view of an alignment strap located along a back corner where two reflective facets meet.

FIG. 8 shows a detailed view of a Velcro alignment strap located along a back corner where two reflective facets meet.

Several drawings and illustrations have been presented to better explain the construction and functioning of embodiments of the present invention. The scope of the present invention is not limited to what is shown in the figures.

### DESCRIPTION OF THE INVENTION

The present invention uses a simple arrangement of flat reflectors or reflective facets arranged around a solar cell or solar panel to increase the amount of light arriving at the solar cell or panel, with the object of reducing the average cost of solar power.

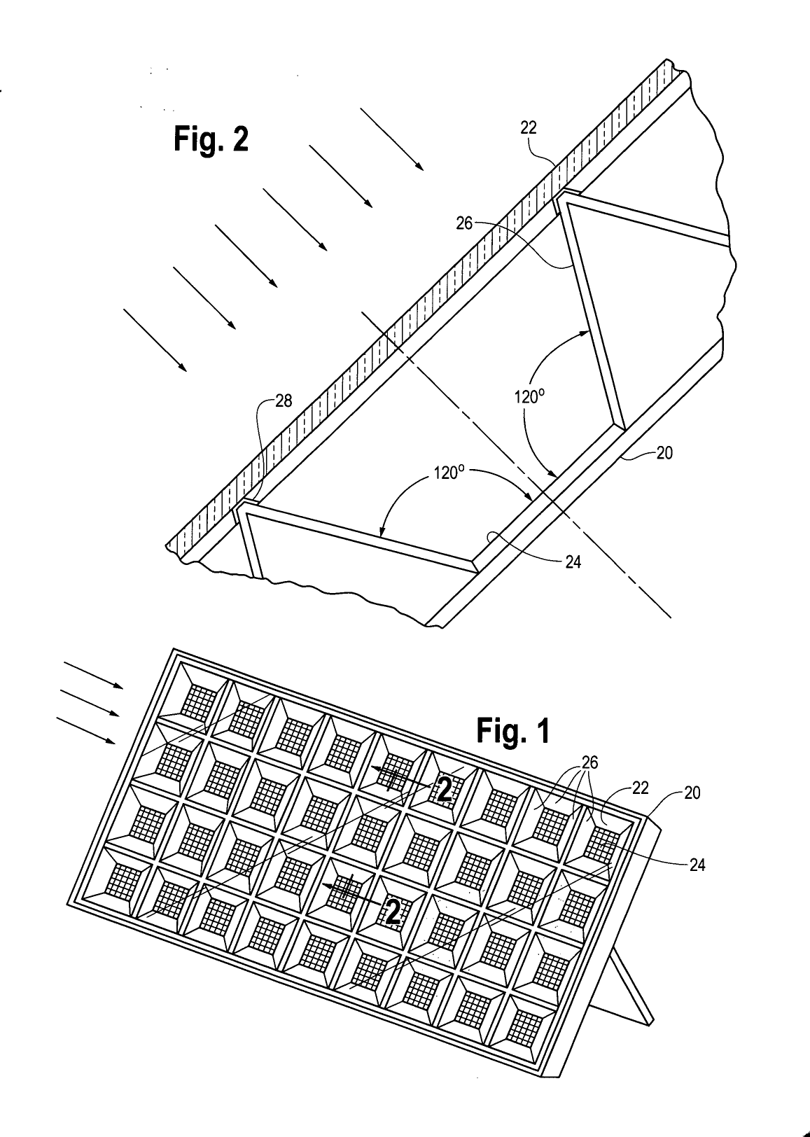

FIG. 1 shows a perspective view of a solar panel constructed according to an embodiment of this invention. Similar to prior art solar panels, this invention employs a repeating pattern of solar cells 24 that are contained within a panel frame 20 and disposed parallel to and under a transparent cover 22. Unlike prior art solar panels, in the preferred embodiment each solar cell 24 has a reflective facet 26 located adjacent to each side of the solar cell 24, which is disposed at an obtuse angle relative to the solar cell 24 and extending upward toward the transparent cover 22. Assuming the solar cell 24 is approximately square (quite common), each of the four reflective facets 26 will be flat and have an equivalent isosceles trapezoid shape with the shorter parallel side located adjacent to the solar cell 24. The reflective facets 26 will tilt upward and away from the solar cell 24 (at an obtuse angle) in the direction of the transparent cover 22.

If the solar cell 24 is rectangular, then only the reflective facets 26 on opposite sides of the solar cell 24 may have an equivalent isosceles trapezoid shape, but the shorter parallel side of each pair of equivalent reflective facets 26 will be located adjacent to the corresponding length side of the solar cell 24.

FIG. 2 shows a side view of multiple reflective facets 26 arranged around the solar cell 24 in accordance with the preferred embodiment of this invention. This view clearly shows that the solar cell 24 is parallel to, but below the transparent cover 22. It also shows flat reflective facets 26 located with one parallel side adjacent to the solar cell 24 disposed at a 120 degree angle and the other side adjacent to the transparent cover 22. Additionally given this geometry, the reflective facets 26 can be the same width across (or slightly wider) as the solar cell 24 to ensure the extra light uniformly illuminates the solar cell 24. This can be especially important for PV applications. One can utilize the regularly spaced reflective facets 26 to provide extra support for the transparent cover 22 distributing the load across the entire panel rather than placing the load principally on the panel frame 20. An optional gasket 28 may be placed between the top side of the flat reflective facet 26 and the transparent cover 22 to prevent damage to or reduce stress on the transparent cover 22.

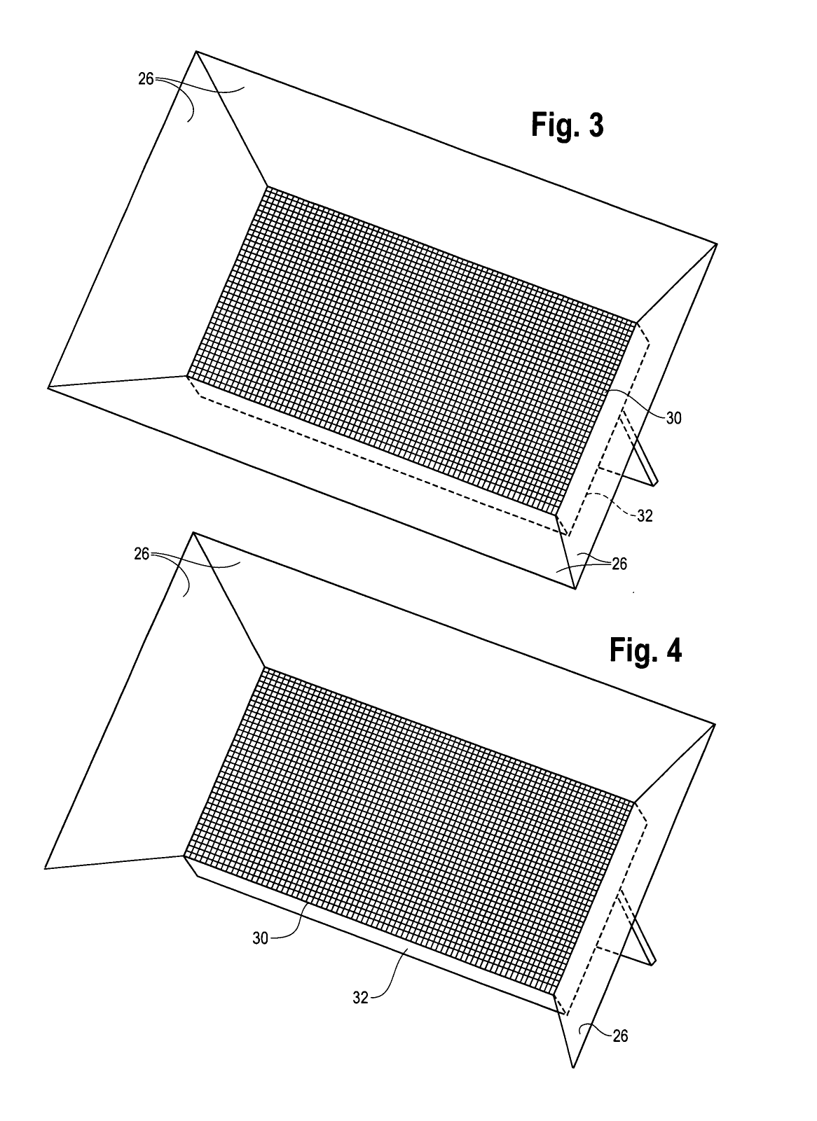

FIG. 3 shows a perspective view of multiple reflector facets 26 arranged around the outside of a standard solar panel 30. Because the standard solar panel 30 is rectangular, it has equivalent isosceles trapezoid shaped reflective facets 26 paired along opposite sides, with the shorter parallel side of each pair located adjacent to the corresponding length side of the standard solar panel 30. Once again the reflective facets 26 should be arranged such that the reflective facets 26 tilt upward and away from the standard solar panel 30 at an obtuse angle. While an obtuse angle of 120 degrees is frequently optimal, similar results may be achieved if the obtuse angle is in the range of 110-130 degrees, provided one varies the width dimension between the parallel sides of the reflective facets 26 to ensure uniform illumination of the solar panel 30.

FIG. 4 shows a perspective view of an alternative embodiment of reflector facets 26 arranged around only 3 sides of a standard solar panel 30. Although in general this design works best when all sides of the standard solar panel 30 have reflective facets 26 located adjacent and at an obtuse angle relative to them, in certain cases it may be advantageous to only surround 3 sides of the standard solar panel 30, as described above.

FIG. 5 shows a perspective view of a standard solar panel 30 with reflector facets 26 arranged around it from the back. In this view each isosceles trapezoid shaped reflective facet 26 has its shorter parallel edge attached to the corresponding length side of the solar panel 32 and the back side of the reflective facets 26 are aligned in the top corner where they meet.

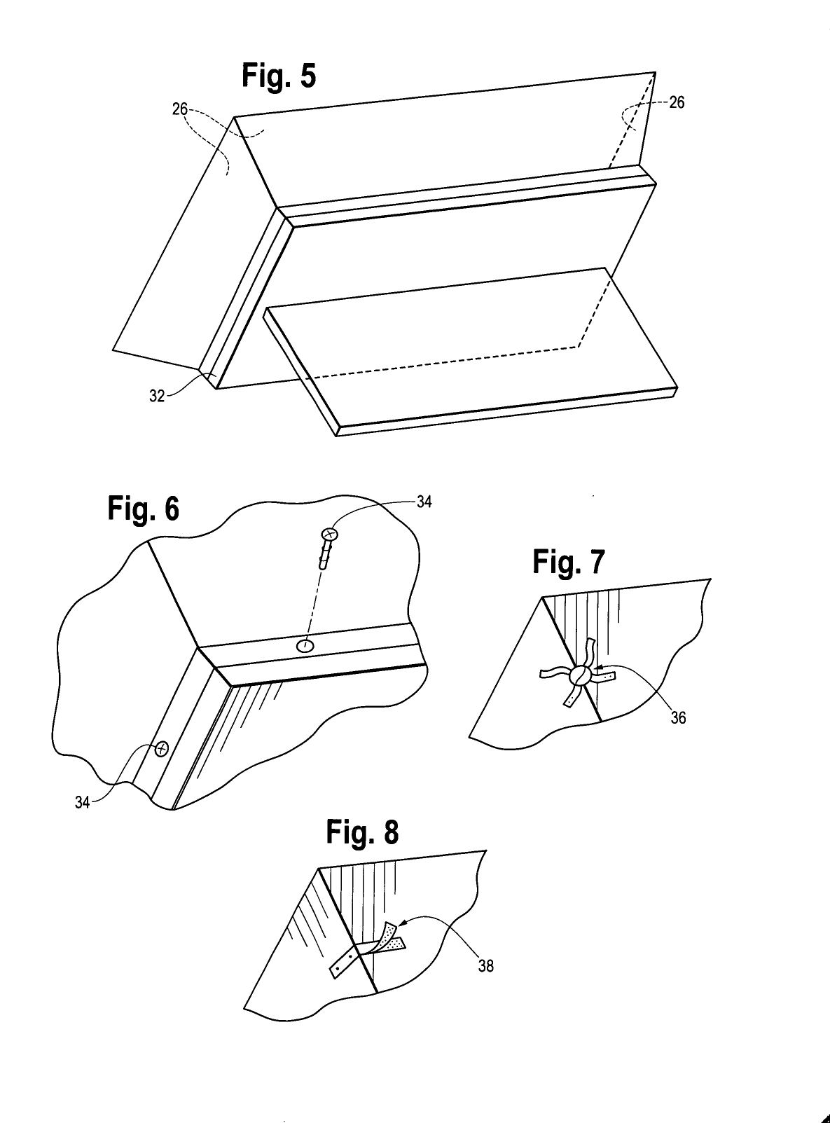

FIG. 6 shows an exploded view of one means for mounting the reflective facets 26 to the side of the solar panel 32 using mounting screws 34. The mounting screw 34 goes through the bottom edge of the reflective facet 26. This bottom edge may be bent to press flush to the side of the solar panel 32 for mounting. There are numerous additional means that could be used for mounting the reflective facets 26 to the side of the solar panel 32 which are not shown.

These additional means include but are not limited to: mounting clips which may be attached to the side of the solar panel 32 capable of securing—through friction or a spring force—the reflective facets 26 in place in the desired orientation, mounting slots cut into the frame of a standard solar panel 30 that serve to capture the reflective facets 26 in the desired orientation, or mounting brackets which may be added to the side of the solar panel 32 which serve to hold the reflective facets 26 in the desired orientation.

FIG. 7 shows an enlarged view of an alignment strap 36 placed on the upper back corner of a pair of reflective facets 26 where they meet.

FIG. 8 shows an alternative alignment arrangement specifically an enlarged view of a Velcro alignment strap 38 placed on the upper back corner of a pair of reflective facets 26 where they meet.

In all embodiments, the reflective surfaces can optionally be designed to not reflect wavelengths of sunlight, such as infrared or UV, which might overheat or damage the performance of the solar cell. This is especially useful if the cell is a photovoltaic cell that produces less electricity as the cell temperature rises. In this manner, only useful wavelengths can be directed to the cell from the reflectors.

Several descriptions and illustrations have been presented to aid in understanding the present invention. One of skill in the art will realize that numerous changes and variations are possible without departing from the spirit of the invention. For example, a solar cell may be a hybrid cell capable of both generating electricity via photovoltaic effect and transferring thermal energy to a circulating fluid in contact with the cell. Each of these changes and variations is within the scope of the present invention.

I claim:

1. A solar collector for maximizing collection of useful sunlight comprising:
a) an enclosure comprising four sides, and a transparent cover that protects interior surfaces from the elements (other than sunlight);
b) at least one rectangular solar cell mounted parallel to, and below the transparent cover; and,
c) a plurality of flat reflective facets surrounding said solar cell, with each said reflective facet located adjacent to one side of said solar cell, and mounted at an obtuse angle relative to the surface of said solar cell, such that said reflective facets extend upward toward said transparent cover.

2. The solar collector of claim 1 wherein said solar cell absorbs solar radiation and transfers it to a working fluid.

3. The solar collector of claim 1 wherein said solar cell comprises a photovoltaic cell for converting light to electricity.

4. The solar collector of claim 3 wherein said reflective facet reflects primarily wavelengths of light said photovoltaic cell converts efficiently to electricity, while not reflecting wavelengths that tend to primarily heat said photovoltaic cell.

5. The solar collector of claim 1 wherein said reflective facets are shaped like isosceles trapezoids with the shorter parallel side located adjacent to one side of said solar cell.

6. The solar collector of claim 1 further comprising a plurality of solar cells with each said solar cell surrounded by a plurality of flat reflective facets.

7. The solar collector of claim 1 wherein the obtuse angle is approximately 120 degrees.

8. The solar collector of claim 1 wherein the obtuse angle lies in the range between 110-130 degrees.

9. The solar collector of claim 1 wherein said plurality of flat reflective facets form a single piece reflector shaped like an inverted, truncated, four-sided, pyramid shell.

10. The solar collector of claim 1 wherein said reflective facets are aluminum.

11. A solar collector for maximizing collection of useful sunlight comprising:
a) a standard solar panel with four sides;
b) a plurality of flat reflective facets surrounding said solar panel, with each said reflective facet located adjacent to one side and arranged at an obtuse angle to the surface of said solar panel, such that said reflective facet extends upward and away
c) a means for mounting said flat reflective facets to the sides of said solar panel at said obtuse angle.

12. The solar collector of claim 11 wherein said solar panel absorbs solar radiation and transfers it to a working fluid.

13. The solar collector of claim 11 wherein the said solar panel coverts sunlight to electricity.

14. The solar collector of claim 11 wherein the obtuse angle is approximately 120 degrees.

15. The solar collector of claim 11 wherein the obtuse angle lies in the range between 110-130 degrees.

16. The solar collector of claim 11 wherein said reflective facets are aluminum.

17. The solar collector of claim 11 wherein said reflective facets form a single piece reflector shaped like an inverted, truncated four sided pyramid shell.

18. The solar collector of claim 11 wherein said mounting means comprises, screwing said reflective facets into the sides of said solar panel, and placing alignment straps along the upper back corner wherever two reflective facets meet as necessary to maintain alignment between said reflective facets.

19. The solar collector of claim 11 wherein only three reflective facets are located along three sides of said solar panel.

20. A method for maximizing the collection of useful sunlight onto a rectangular solar device such as a solar cell or a standard solar panel comprising the steps of:
arranging flat reflective facets adjacent to each side of said solar device;
tilting said reflective facets such that approximately a 120 degree angle forms between said flat reflective facet and the surface of said solar device;
mounting said reflective facets to maintain the specified orientation between said reflective facets and said surface of said solar device.
